(19) United States
(12) Patent Application Publication
(10) Pub. No.: US 2012/0133632 A1
(43) Pub. Date: May 31, 2012

(54) OPERATIONAL AMPLIFIER AND DISPLAY DRIVING CIRCUIT USING THE SAME

(75) Inventor: Xie-Ren HSU, Hsinchu City (TW)

(73) Assignee: NOVATEK MICROELECTRONICS CORP., Hsinchu (TW)

(21) Appl. No.: 13/303,965

(22) Filed: Nov. 23, 2011

(30) Foreign Application Priority Data
Nov. 25, 2010 (TW) 99140852

(51) Int. Cl. G09G 5/00; H03F 3/45

(52) U.S. Cl. 345/211; 330/253

(57) ABSTRACT

An operation amplifier, coupled to a control unit, includes: a differential input pair, coupled to an input signal and an output signal; a bias current source, couple to the differential input pair; an output stage, coupled to the bias current source; and a clamp circuit, coupled to the output stage. In discharge, when the control circuit is temporarily short circuit, an internal charge share inside the operational amplifier transiently lowers a first node voltage of the output stage and the clamp circuit pulls high the first node voltage of the output stage. In charge, when the control circuit is temporarily short circuit, an internal charge share inside the operational amplifier transiently pulls high a second node voltage of the output stage and the clamp circuit pulls low the second node voltage of the output stage.

This application claims the benefit of Taiwan application Serial No. 99140852, filed Nov. 25, 2010, the subject matter of which is incorporated herein by reference.

### TECHNICAL FIELD

The disclosure relates in general to an operational amplifier and a display driving circuit using the same.

### BACKGROUND

Referring to FIG. 1, a circuit diagram of an analog output circuit of a prior display driving circuit is shown. An analog output circuit 100 includes a gamma resistor voltage divider 110, two digital-to-analog converters (DAC) 120A˜120B, two operational amplifiers 130A˜130B, four output switches SW1˜SW4 and a charge sharing switch SW_CH. Resistor R and capacitor C denote an equivalent model of a liquid crystal panel. The digital-to-analog converter 120A outputs a positive-polarity voltage and the digital-to-analog converter 120B outputs a negative-polarity voltage. The operational amplifiers 130A˜130B drive the positive-polarity voltage and the negative-polarity voltage respectively. The positive-polarity voltage is larger than a median of the output voltage range of the source driver, and the negative-polarity voltage is smaller than the median of the output voltage range of the source driver. VG1˜VGN denote N reference voltages, and AVO1 and AVO2 denote two external output nodes.

In a data loading phase, input data DAC_ODD and DAC_EVEN are respectively transmitted to the digital-to-analog converter 120A and the digital-to-analog converter 120B and converted by the digital-to-analog converter 120A and the digital-to-analog converter 120B. Under control of control signals POPC1, POPC2, NOPC1 and NOPC2, the output switches SW1˜SW4 are cut off, and the source driver viewed is in a high impedance state. In a charge sharing phase, a control signal EQC is transited to a second level (such as a high potential VDD), so that the charge sharing switch SW_CH is short-circuited, and charges on adjacent channels are redistributed and the levels CH_ODD and CH_EVEN on the loading reach a median value. After the charge sharing phase finishes, the control signal EQC is transited again so that the charge sharing switch SW_CH is cut off to complete charge sharing. Then, the analog output circuit 100 enters an operational amplifier output phase.

If the output node CH_ODD is to output the positive-polarity potential and the output node CH_EVEN is to output the negative-polarity potential, under control of the control signals POPC1, POPC2, NOPC1 and NOPC2, the output switches SW1 and SW2 are turned on and the output switches SW3 and SW4 are cut off for outputting the output voltages of the digital-to-analog converter 120A and the digital-to-analog converter 120B to the output nodes CH_ODD and CH_EVEN through the unity-gain operational amplifier 130A and the unity-gain operational amplifier 130B.

Likewise, if the output node CH_ODD is to output the negative-polarity potential and the output node CH_EVEN is to output the positive-polarity potential, under control of the control signals POPC1, POPC2, NOPC1 and NOPC2, the output switches SW1 and SW2 are cut off and the output switches SW3 and SW4 are turned on for outputting the output voltages of the digital-to-analog converter 120A and the digital-to-analog converter 120B to the output nodes CH_EVEN and CH_ODD through the unity-gain operational amplifier 130A and the unity-gain operational amplifier 130B.

Let charging be taken for example. In the data loading phase, the operational amplifier starts charging after receiving data. In the operational amplifier output phase, the output switch is transiently short-circuited, and internal operations of the operational amplifier will be interfered, which causes unexpected occurrences in the operational amplifier circuit.

### SUMMARY OF THE DISCLOSURE

The disclosure is directed to an operational amplifier and a display driving circuit using the same. A clamp circuit is used to reduce interference on the operational amplifier, which occurs when an output switch is transiently short-circuited, so as to reduce unexpected occurrences such as current leakage of the operational amplifier circuit.

According to an exemplary embodiment of the disclosure, an operational amplifier is provided. The operational amplifier, coupled to a control unit, includes a differential input pair coupled to an input signal and an output signal, a bias current source coupled to the differential input pair, an output stage coupled to the bias current source, and a clamp circuit coupled to the output stage. During discharging, when the control unit is temporarily short-circuited, a first node voltage of the output stage is transiently lowered by an internal charge share inside the operational amplifier, and the clamp circuit pulls high the first node voltage of the output stage. During charging, when the control unit is temporarily short-circuited, a second node voltage of the output stage is transiently pulled high by the internal charge share inside the operational amplifier, and the clamp circuit pulls low the second node voltage of the output stage.

According to another exemplary embodiment of the disclosure, a display driving circuit is provided. The display driving circuit includes a control unit and an operational amplifier coupled to the control unit. The operational amplifier includes a differential input pair coupled to an input signal and an output signal, a bias current source coupled to the differential input pair, an output stage coupled to the bias current source, and a clamp circuit coupled to the output stage. During discharging, when the control unit is temporarily short-circuited, a first node voltage of the output stage is transiently lowered by an internal charge share inside the operational amplifier, and the clamp circuit pulls high the first node voltage of the output stage. During charging, when the control unit is temporarily short-circuited, a second node voltage of the output stage is transiently pulled high by the internal charge share inside the operational amplifier, and the clamp circuit pulls low the second node voltage of the output stage.

It is to be understood that both the foregoing general description and the following detailed description are exemplary and explanatory only and are not restrictive of the disclosed embodiments, as claimed.

### BRIEF DESCRIPTION OF THE DRAWINGS

FIG. 1 (prior art) shows a circuit diagram of a prior display driver;

FIG. 2 and FIG. 3 respectively show a circuit diagram and a timing diagram of an operational amplifier according to a first embodiment of the disclosure;

FIG. 4 and FIG. 5 respectively show a circuit diagram and a timing diagram of an operational amplifier according to a second embodiment of the disclosure; and

FIG. 6 and FIG. 7 respectively show a circuit diagram and a timing diagram of an operational amplifier according to a third embodiment of the disclosure.

### DETAILED DESCRIPTION OF THE DISCLOSURE

In embodiments of the disclosure, an operational amplifier circuit is appropriately and timely controlled in an analog control manner, a digital control manner or a combination thereof. Thus, when the operational amplifier circuit enters an operational amplifier output phase from a data loading phase, the transient turn-on of an output switch will not interfere with the operational amplifier circuit, for preventing the operational amplifier circuit from unexpected occurrences (such as current leakage).

### First Embodiment

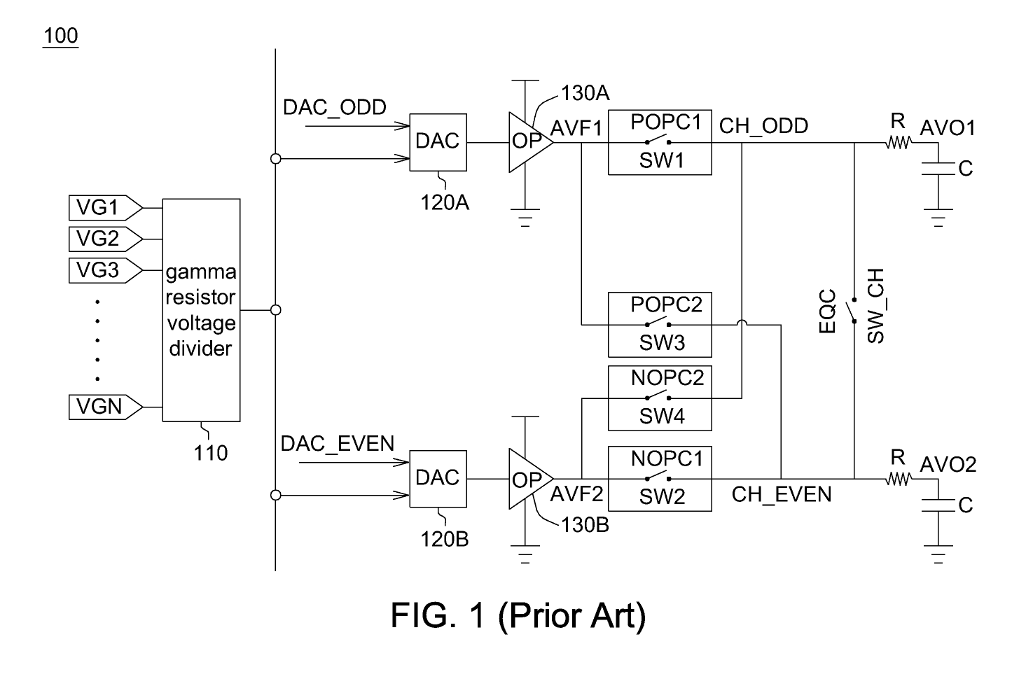

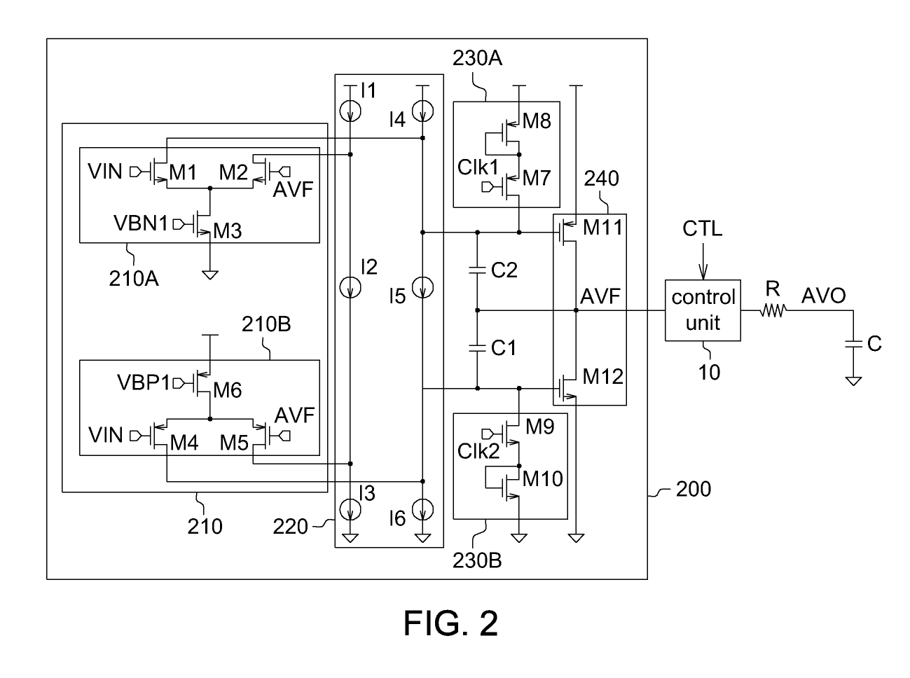

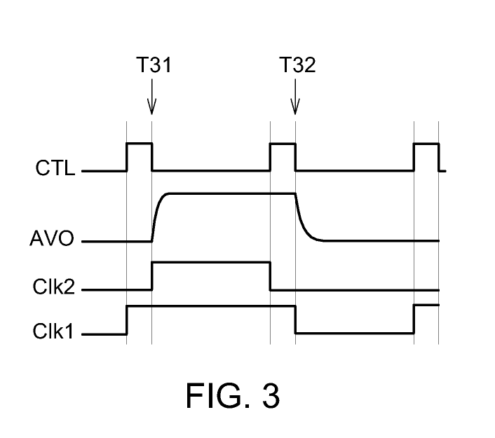

Referring to FIG. 2 and FIG. 3, a circuit diagram and a timing diagram of an operational amplifier according to a first embodiment of the disclosure are respectively shown. As indicated in FIG. 2, an operational amplifier 200 of the first embodiment of the disclosure includes a differential input pair 210, a bias current source 220, clamp circuits 230A˜230B, an output stage 240 and compensation capacitors C1˜C2. The operational amplifier 200 may be used in an analog output circuit of a source drive circuit but is not limited thereto. The control unit 10 may be realized by any of the output switches SW1˜SW4 of FIG. 1 but is not limited thereto.

The differential input pair 210 includes an NMOS differential input pair 210A and a PMOS differential input pair 210B. The NMOS differential input pair 210A includes three NMOS the transistors M1˜M3. The PMOS differential input pair 210B includes three PMOS transistors M4˜M6. The gate of the transistor M1 receives an input signal VIN (such as but is not limited to the output signal of the digital-to-analog converter of FIG. 1), the source of the transistor M1 is coupled to the source of the transistor M2 and the drain of the transistor M3, and the drain of the transistor M1 is coupled to the bias current source 220. The gate of the transistor M2 is coupled to the output signal AVF (such as but is not limited to the output signal AVF1 of the operational amplifier 130A of FIG. 1), the source of the transistor M2 is coupled to the source of the transistor M1 and the drain of the transistor M3, and the drain of the transistor M2 is coupled to the bias current source 220. The gate of the transistor M3 receives a bias voltage VBN1, the source of the transistor M3 is coupled to the grounding end, and the drain of the transistor M3 is coupled to the source of the transistor M1 and the source of the transistor M2. The gate of the transistor M4 receives the input signal VIN, the source of the transistor M4 is coupled to the source of the transistor M5 and the drain of the transistor M6, the drain of the transistor M4 is coupled to the bias current source 220. The gate of the transistor M5 is coupled to the output signal AVF, the source of the transistor M5 is coupled to the source of the transistor M4 and the drain of the transistor M6, and the drain of the transistor M5 is coupled to the bias current source 220. The gate of the transistor M6 receives a bias voltage VBP1, the source of the transistor M6 is coupled to the operating voltage, and the drain of the transistor M6 is coupled to the source of the transistor M4 and the source of the transistor M5.

The bias current source 220 includes six current sources I1˜I6. The current source I1 is coupled between an operating voltage and the drain of the transistor M2. The current source I2 is coupled between the drain of the transistor M2 and the drain of the transistor M5. The current source I3 is coupled between the drain of the transistor M5 and the grounding end. The current source I4 is coupled between the operating voltage and the drain of the transistor M1. The current source I5 is coupled between the drain of the transistor M1 and the drain of the transistor M4. The current source I6 is coupled between the drain of the transistor M4 and the grounding end.

The clamp circuit 230A includes two transistors M7 and M8. The clamp circuit 230B includes two transistors M9 and M10. The gate of the transistor M7 receives a control signal Clk1, the source of the transistor M7 is coupled to the drain and the gate of the transistor M8, and the drain of the transistor M7 is coupled to the gate of the transistor M11 of the output stage 240. The transistor M8 may be realized by such as a diode-connected transistor, wherein the gate and the drain of the transistor M8 are both connected to the source of the transistor M7, and the source of the transistor M8 is coupled to the operating voltage. The gate of the transistor M9 receives a control signal Clk2, the source of the transistor M9 is coupled to the drain and the gate of the transistor M10, and the drain of the transistor M9 is coupled to the gate of the transistor M12 of the output stage 240. The transistor M10 may be realized by such as a diode-connected transistor, wherein the gate and the drain of the transistor M10 are both connected to the source of the transistor M9, and the source transistor M10 is coupled to the grounding end.

The output stage 240 includes two transistors M11 and M12. The gate of the transistor M11 is coupled to the drain of the transistor M7 of the clamp circuit 230A, the source of the transistor M11 is coupled to the operating voltage, and the drain of the transistor M11 is coupled to the output signal AVF. The gate of the transistor M12 is coupled to the drain of the transistor M9 of the clamp circuit 230B, the source of the transistor M12 is coupled to the grounding end, and the drain of the transistor M12 is coupled to the output signal AVF.

The compensation capacitor C1 is coupled between the gate of the transistor M11 and the output signal AVF, and the compensation capacitor C2 is coupled between the gate of the transistor M12 and the output signal AVF.

When the control signal CTL is at low potential, the control unit 10 is cut off for example. To the contrary, when the control signal CTL is at high potential, the control unit 10 is short-circuited (turned on).

The operation of the operational amplifier of the first embodiment of the disclosure is elaborated below with accompanying diagrams FIGS. 2 and 3. Let charging be taken for example. The operational amplifier 200 starts after receiving the input signal VIN, so that the potential of the output signal AVF may be identical to that of the input signal VIN. In the operational amplifier output phase, under control of the control signal CTL, the control unit 10 is transiently short-circuited, and the output signal AVF share charge with the output signal AVO maintained at the previous state, so that the gate voltage of the transistor M12 is temporarily pulled high. However, the internal operation of the operational amplifier will be interfered with. As indicated in FIG. 3, at timing T31, the control unit 10 is transiently short-circuited, the output signal AVF shares charge with the output signal AVO maintained at a low potential.

At timing T31, the control signal Clk2 is at high potential, the transistor M9 (used as a switch) is turned on, and the diode-connected transistor M10 is turned on under suitable circumstances, so that the gate voltage of the transistor M12 is lowered until the gate voltage of the transistor M12 is insufficient to turn on the diode-connected transistor M10, for preventing the operational amplifier from unexpected current leakage.

Likewise, during discharging, the operational amplifier 200 starts discharging after receiving the input signal VIN, so that the output signal AVF is discharged to be identical to the input signal VIN. In the operational amplifier output phase, under control of the control signal CTL, the control unit 10 is transiently short-circuited, the output signal AVF shares charge with the output signal AVO maintained at the previous state, so that the gate voltage of the transistor M11 is temporarily lowered. However, the internal operation of the operational amplifier will be interfered with. At timing T32, the control signal Clk1 is at low potential, the transistor M7 (used as a switch) is turned on, and the diode-connected transistor M8 will be turned on under suitable circumstances, so that the gate voltage of the transistor M11 is pulled high until a voltage difference between the operating voltage and the gate voltage of the transistor M11 is insufficient to turn on the diode-connected transistor M8, for preventing the operational amplifier from unexpected current leakage.

That is, in the first embodiment, the clamp circuit is used to clamp the gate voltage of the transistor of the output stage, so as to improve the negative impacts which may occur when the operational amplifier is transiently turned on by the output switch.

According to the first embodiment of the disclosure disclosed above, the change in the internal state of the operational amplifier is detected and controlled by the diode-connected transistors M8 and M10 through the digital control (the ON/OFF of the transistor being digitally controlled by the control signal) and the analog control (by the diode-connected transistors), for preventing the operational amplifier from unexpected occurrences.

### Second Embodiment

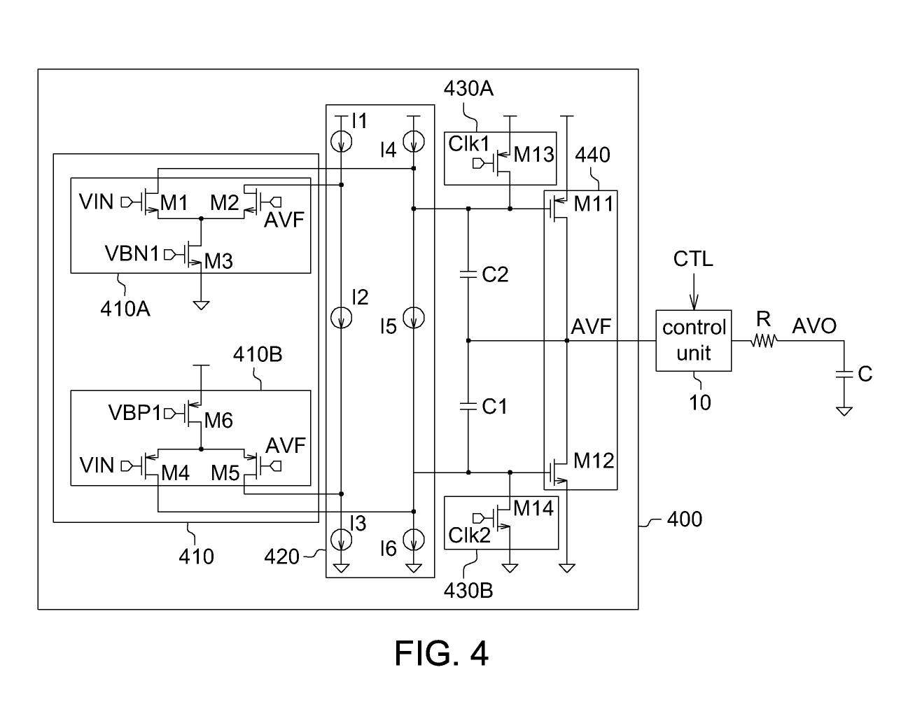

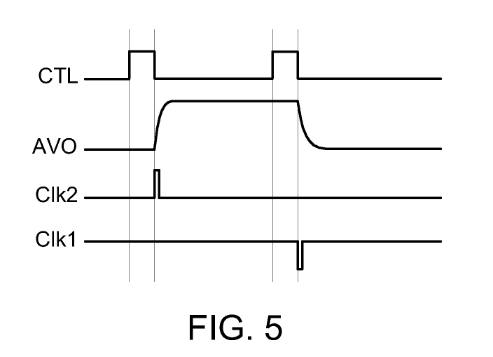

Referring to FIG. 4 and FIG. 5, a circuit diagram and a timing diagram of an operational amplifier according to a second embodiment of the disclosure are respectively shown. As indicated in FIG. 4, an operational amplifier 400 of the second embodiment of the disclosure includes a differential input pair 410, a bias current source 420, two clamp circuits 430A˜430B, an output stage 440 and two compensation capacitors C1˜C2. The differential input pair 410 includes an NMOS differential input pair 410A and a PMOS differential input pair 410B. Since the circuit architecture of the second embodiment is similar to that of the first embodiment, the clamp circuits of the second embodiment are elaborated in the disclosure below, and other similarities are omitted.

The clamp circuit 430A includes a transistor M13. The clamp circuit 430B includes a transistor M14. The gate of the transistor M13 receives a control signal Clk1, the source of the transistor M13 is coupled to the operating voltage, and the drain of the transistor M13 is coupled to the gate of the transistor M11 of the output stage 440. The gate of the transistor M14 receives a control signal Clk2, the source of the transistor M14 is coupled to the grounding end, and the drain of the transistor M14 is coupled to the gate of the transistor M12 of the output stage 440.

The operation of the operational amplifier of the second embodiment of the disclosure is elaborated below with accompanying diagrams FIGS. 4 and 5. Let charging be taken for example. The operational amplifier 400 starts charging after receiving the input signal VIN, so that the potential of the output signal AVF may be identical to that of the input signal VIN. In the operational amplifier output phase, under control of the control signal CTL, the control unit 10 is transiently short-circuited, the output signal AVF shares charge with the output signal AVO maintained at the previous state, so that the gate voltage of the transistor M12 is temporarily pulled high. However, the internal operation of the operational amplifier will be interfered with.

When the control signal Clk2 is at high potential, the transistor M14 (used as a switch) is turned on, and the gate voltage of the transistor M12 is lowered until the gate voltage of the transistor M12 is close to the grounding end voltage, for preventing the operational amplifier from unexpected current leakage.

Likewise, during discharging, the operational amplifier 400 starts discharging after receiving the input signal VIN, so that the potential of the output signal AVF is discharged to be identical to that of the input signal VIN. In the operational amplifier output phase, under control of the control signal CTL, the control unit 10 is transiently short-circuited, the output signal AVF shares charge with the output signal AVO maintained at the previous state, so that the gate voltage of the transistor M11 is temporarily lowered. However, the internal operation of the operational amplifier will be interfered with. When the control signal Clk1 is at low potential, the transistor M13 (used as a switch) is turned on, and the gate voltage of the transistor M11 is pulled high to the operating voltage, for preventing the operational amplifier from unexpected current leakage.

According to the second embodiment of the disclosure disclosed above, the change in the internal state of the operational amplifier is detected and controlled through digital control (the ON/OFF of the transistor is digitally controlled by the control signal), for preventing the operational amplifier from unexpected occurrences.

### Third Embodiment

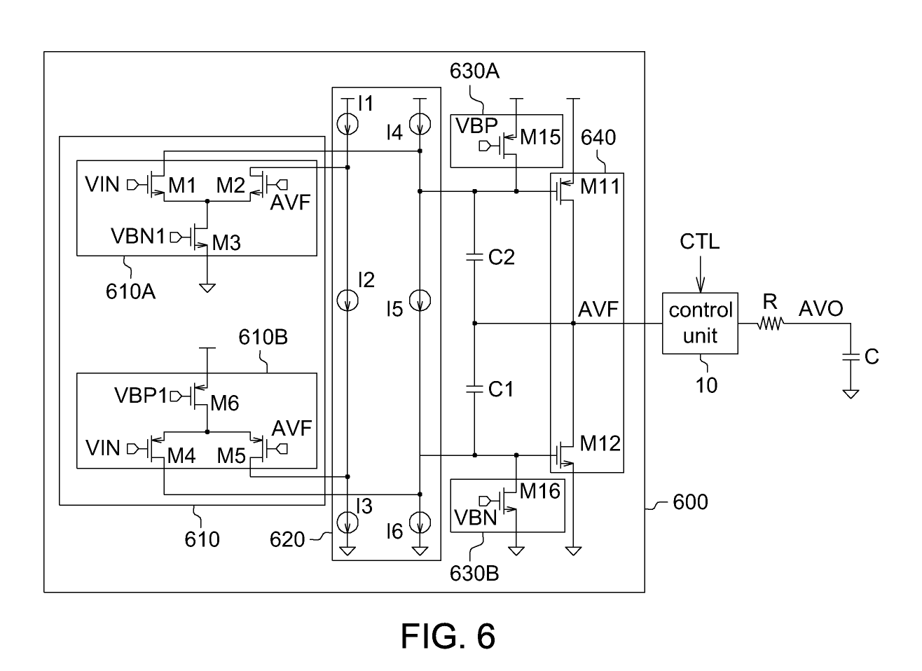

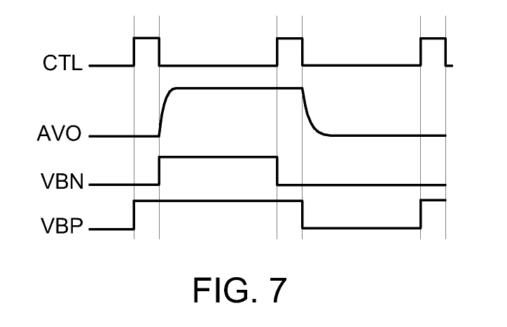

Referring to FIG. 6 and FIG. 7, a circuit diagram and a timing diagram of an operational amplifier according to a third embodiment of the disclosure are respectively shown. As indicated in FIG. 6, an operational amplifier 600 of the third embodiment of the disclosure includes a differential input pair 610, a bias current source 620, two clamp circuits 630A˜630B, an output stage 640 and two compensation capacitors C1˜C2. The differential input pair 610 includes an NMOS differential input pair 610A and a PMOS differential input pair 610B. Since the circuit architecture of the third embodiment is similar to that of the first embodiment, the clamp circuits of the third embodiment are elaborated in the disclosure below, and other similarities are omitted.

The clamp circuit 630A includes a transistor M15. The clamp circuit 630B includes a transistor M16. The gate of the transistor M15 receives a bias voltage VBP, the source of the transistor M15 is coupled to the operating voltage, and the drain of the transistor M15 is coupled to the gate of the transistor M11 of the output stage 640. The gate of the transistor M16 receives a bias voltage VBN, the source of the transistor M16 is coupled to the grounding end, and the drain of the transistor M16 is coupled to the gate of the transistor M12 of the output stage 640.

The operation of the operational amplifier according to the third embodiment of the disclosure is elaborated below with accompanying diagrams FIGS. 6 and 7. Let charging be taken for example. The operational amplifier 600 starts charging after receiving the input signal VIN, so that the potential of the output signal AVF may be identical to that of the input signal VIN. In the operational amplifier output phase, under control of the control signal CTL, the control unit 10 is transiently short-circuited, the output signal AVF shares charge with the output signal AVO maintained at the previous state, so that the gate voltage of the transistor M12 is temporarily pulled high. However, the internal operation of the operational amplifier will be interfered with. When interference occurs, the bias voltage VBN is at high potential so that the transistor M16 is turned on to lower the gate voltage of the transistor M12. The transistor M16 will be turned off (the bias voltage VBN is transited to low potential) as soon as the operational amplifier 600 returns to a steady state.

Likewise, during discharging, the operational amplifier 400 starts discharging after receiving the input signal VIN, so that the potential of the output signal AVF is discharged to be identical to that of the input signal VIN. In the operational amplifier output phase, under control of the control signal CTL, the control unit 10 is transiently short-circuited, the output signal AVF shares charge with the output signal AVO maintained at the previous state, so that the gate voltage of the transistor M11 is temporarily lowered. However, the internal operation of the operational amplifier will be interfered with. When interference occurs, the bias voltage VBP is at low potential so that the transistor M15 is turned on and the gate voltage of the transistor M11 is pulled high. The transistor M15 will be turned off (the bias voltage VBP is transited to high potential) as soon as the operational amplifier 600 returns to a steady state.

According to the third embodiment of the disclosure disclosed above, the change in the internal state of the operational amplifier is detected and controlled through analog control (the ON/OFF of the clamp voltage is analog controlled by the bias voltage), for preventing the operational amplifier from unexpected occurrences.

It will be appreciated by those skilled in the art that changes could be made to the disclosed embodiments described above without departing from the broad inventive concept thereof. It is understood, therefore, that the disclosed embodiments are not limited to the particular examples disclosed, but is intended to cover modifications within the spirit and scope of the disclosed embodiments as defined by the claims that follow.

What is claimed is:

1. An operational amplifier coupled to a control unit, including:
a differential input pair coupled to an input signal and an output signal;
a bias current source coupled to the differential input pair;
an output stage coupled to the bias current source; and
a clamp circuit coupled to the output stage,
wherein,
during discharging, when the control unit is temporarily short-circuited, a first node voltage of the output stage is transiently lowered by an internal charge share inside the operational amplifier, and the clamp circuit pulls high the first node voltage of the output stage; and
during charging, when the control unit is temporarily short-circuited, a second node voltage of the output stage is transiently pulled high by the internal charge share inside the operational amplifier, and the clamp circuit pulls low the second node voltage of the output stage.

2. The operational amplifier according to claim 1, further comprising:
first and second compensation capacitors coupled to the output stage.

3. The operational amplifier according to claim 1, wherein, the clamp circuit comprises:
a first clamp transistor, which receives a first digital control signal and is coupled to the first node voltage of the output stage;
a second clamp transistor, which is a diode-connected transistor and is coupled to the first clamp transistor;
a third clamp transistor, which receives a second digital control signal and is coupled to the second node voltage of the output stage; and
a fourth clamp transistor, which is a diode-connected transistor and is coupled to the third clamp transistor;
during discharging, under control of the first digital control signal, the first clamp transistor is turned on, and the first node voltage of the output stage turns on the second clamp transistor to pull high the first node voltage of the output stage until a voltage difference between an operating voltage and the first node voltage is insufficient to turn on the second clamp transistor; and
during charging, under control of the second digital control signal, the third clamp transistor is turned on, and the second node voltage of the output stage turns on the fourth clamp transistor to lower the second node voltage of the output stage until the second node voltage is insufficient to turn on the fourth clamp transistor.

4. The operational amplifier according to claim 1, wherein, the clamp circuit comprises:
a first clamp transistor, which receives a first digital control signal and is coupled to the first node voltage of the output stage; and
a second clamp transistor, which receives a second digital control signal and is coupled to the second node voltage of the output stage;
during discharging, under control of the first digital control signal, the first clamp transistor is turned on to pull high the first node voltage of the output stage; and
during charging, under control of the second digital control signal, the second clamp transistor is turned on to lower the second node voltage of the output stage.

5. The operational amplifier according to claim 1, wherein, the clamp circuit comprises:
a first clamp transistor, which receives a first analog bias voltage and is coupled to the first node voltage of the output stage; and
a second clamp transistor, which receives a second analog bias voltage and is coupled to the second node voltage of the output stage;
during discharging, under control of the first analog bias voltage, the first clamp transistor is turned on to pull high the first node voltage of the output stage until the operational amplifier returns to a steady state; and
during charging, under control of the second analog bias voltage, the second clamp transistor is turned on to lower the second node voltage of the output stage until the operational amplifier returns to a steady state.

6. A display driving circuit, comprising:
a control unit; and
an operational amplifier coupled to the control unit, including:
a differential input pair coupled to an input signal and an output signal;
a bias current source coupled to the differential input pair;
an output stage coupled to the bias current source; and
a clamp circuit coupled to the output stage,
wherein,
during discharging, when the control unit is temporarily short-circuited, a first node voltage of the output stage is transiently lowered by an internal charge share inside the operational amplifier, and the clamp circuit pulls high the first node voltage of the output stage; and
during charging, when the control unit is temporarily short-circuited, a second node voltage of the output stage is transiently pulled high by the internal charge share inside the operational amplifier, and the clamp circuit pulls low the second node voltage of the output stage.

7. The display driving circuit according to claim 6, wherein the operational amplifier further comprises:
first and second compensation capacitors coupled to the output stage.

8. The display driving circuit according to claim 6, wherein, the clamp circuit comprises:
a first clamp transistor, which receives a first digital control signal and is coupled to the first node voltage of the output stage;
a second clamp transistor, which is a diode-connected transistor coupled to the first clamp transistor;
a third clamp transistor, which receives a second digital control signal and is coupled to the second node voltage of the output stage; and
a fourth clamp transistor, which is a diode-connected transistor and is coupled to the third clamp transistor;
during discharging, under control of the first digital control signal, the first clamp transistor is turned on, and the first node voltage of the output stage turns on the second clamp transistor to pull high the first node voltage of the output stage until a voltage difference between an operating voltage and the first node voltage is insufficient to turn on the second clamp transistor; and
during charging, under control of the second digital control signal, the third clamp transistor is turned on, and the second node voltage of the output stage turns on the fourth clamp transistor to lower the second node voltage of the output stage until the second node voltage is insufficient to turn on the fourth clamp transistor.

9. The display driving circuit according to claim 6, wherein, the clamp circuit comprises:
a first clamp transistor, which receives a first digital control signal and is coupled to the first node voltage of the output stage; and
a second clamp transistor, which receives a second digital control signal and is coupled to the second node voltage of the output stage;
during discharging, under control of the first digital control signal, the first clamp transistor is turned on to pull high the first node voltage of the output stage; and
during charging, under control of the second digital control signal, the second clamp transistor is turned on to lower the second node voltage of the output stage.

10. The display driving circuit according to claim 6, wherein, the clamp circuit comprises:
a first clamp transistor, which receives a first analog bias voltage and is coupled to the first node voltage of the output stage; and
a second clamp transistor, which receives a second analog bias voltage and is coupled to the second node voltage of the output stage;
during discharging, under control of the first analog bias voltage, the first clamp transistor is turned on to pull high the first node voltage of the output stage until the operational amplifier returns to a steady state; and
during charging, under control of the second analog bias voltage, the second clamp transistor is turned on to lower the second node voltage of the output stage until the operational amplifier returns to a steady state.
